(19) United States
(12) Patent Application Publication
(10) Pub. No.: US 2025/0278541 A1
(43) Pub. Date: Sep. 4, 2025

(54) SYSTEMS AND METHODS FOR OBJECT FEEDING

(71) Applicants: Xuan TAN, Birmingham, AL (US); Hao YU, Birmingham, AL (US); Yingyu LI, Birmingham, AL (US)

(72) Inventors: Xuan TAN, Birmingham, AL (US); Hao YU, Birmingham, AL (US); Yingyu LI, Birmingham, AL (US)

(21) Appl. No.: 19/067,797

(22) Filed: Feb. 28, 2025

Related U.S. Application Data
(60) Provisional application No. 63/560,615, filed on Mar. 1, 2024.

(51) Int. Cl. G06F 30/27; A01K 5/01

(52) U.S. Cl. CPC G06F 30/27; A01K 5/0114

(57) ABSTRACT

The present disclosure provides systems and methods for object feeding. The methods may include obtaining a target image including a feeding object. The methods may include determining, based on the target image, an appearance feature of the feeding object. The appearance feature may at least include a breed-specific feature, a body size feature, and a body proportion feature. The methods may further include determining, based on the appearance feature of the feeding object, a recommended parameter relating to a feeding bowl for the feeding object through a recommendation model. The recommendation model may be a machine learning model.

### CROSS-REFERENCE TO RELATED APPLICATIONS

This application claims priority to U.S. Provisional Patent Application No. 63/560,615, filed on Mar. 1, 2024, the contents of which are hereby incorporated by reference.

### TECHNICAL FIELD

The present disclosure generally relates to the field of pet supplies, and more particularly, relates to systems and methods for object feeding.

### BACKGROUND

The pet product industry is experiencing a significant transformation towards personalization, as evidenced by the growing trend of developing elevated bowl products for pets. In parallel, there is an increasing focus on designing feeding bowls with varied angles and shapes to accommodate the diverse facial structures of different pets. For instance, bowls designed for flat-faced dog breeds are distinct from those intended for long-nosed breeds, and cat bowls are specifically designed to prevent contact with the sensitive whiskers of cats.

Therefore, it is desired to provide systems and methods for object feeding, which can personalize recommended parameters of the feeding bowls.

### SUMMARY

According to an aspect of the present disclosure, a method for object feeding is provided. The method may be implemented on a computing device having at least one processor and at least one storage device. The method may include obtaining a target image including a feeding object. The method may include determining, based on the target image, an appearance feature of the feeding object. The appearance feature may at least include a breed-specific feature, a body size feature, and a body proportion feature. The method may further include determining, based on the appearance feature of the feeding object, a recommended parameter relating to a feeding bowl for the feeding object through a recommendation model. The recommendation model may be a machine learning model.

In some embodiments, the determining, based on the target image, an appearance feature of the feeding object may include determining the appearance feature of the feeding object by inputting the target image into a feature determination model. The feature determination model may be a machine learning model.

In some embodiments, the determining, based on the target image, an appearance feature of the feeding object may include determining, based on the target image, the breed-specific feature of the feeding object; determining, based on the target image, the body size feature of the feeding object; and determining the body proportion feature of the feeding object based on the breed-specific feature and the body size feature of the feeding object.

In some embodiments, the target image may include a reference object, and the determining, based on the target image, the body size feature of the feeding object may include obtaining a size of the reference object; and determining the body size feature of the feeding object based on the size of the reference object and a dimensional relationship between the feeding object and the reference object.

In some embodiments, the obtaining a size of the reference object may include determining whether the reference object is a known reference object; in response to determining that the reference object is a known reference object, obtaining the size of the reference object based on a record of the reference object; or in response to determining that the reference object is not a known reference object, receiving a user input of the size of the reference object.

In some embodiments, the determining, based on the target image, the body size feature of the feeding object may include obtaining imaging information relating to the target image, the imaging information at least including parametric information of an image acquisition device used for collecting the target image; and determining the body size feature of the feeding object based on the target image and the imaging information.

In some embodiments, the determining the body proportion feature of the feeding object based on the breed-specific feature and the body size feature of the feeding object may include retrieving the body proportion feature of the feeding object from a feeding object database based on the breed-specific feature and the body size feature of the feeding object. The feeding object database may be constructed based on appearance data of reference feeding objects of a plurality of breeds.

In some embodiments, the retrieving the body proportion feature of the feeding object from a feeding object database based on the breed-specific feature and the body size feature of the feeding object may include determining a key feature value of the feeding object based on the body size feature of the feeding object; and retrieving the body proportion feature of the feeding object from the feeding object database by matching the key feature value and the breed-specific feature of the feeding object with candidate body proportion features in the feeding object database.

In some embodiments, the target image may include multiple target images, and the appearance feature of the feeding object may be determined by: constructing a three-dimensional (3D) model of the feeding object based on the multiple target images; and determining, based on the 3D model of the feeding object, the appearance feature of the feeding object.

In some embodiments, the determining, based on the appearance feature of the feeding object, a recommended parameter relating to a feeding bowl for the feeding object through a recommendation model may include obtaining a feeding feature of the feeding object; and determining the recommended parameter for the feeding object by inputting the appearance feature and the feeding feature of the feeding object into the recommendation model.

In some embodiments, the method may further include obtaining a feeding feature of the feeding object; determining, based on the feeding feature, an adjustment coefficient of the recommended parameter; and adjusting the recommended parameter based on the adjustment coefficient.

In some embodiments, the method may further include sending the appearance feature of the feeding object to a user; receiving user feedback on the appearance feature of the feeding object; and in response to determining that the user feedback indicates the appearance feature needs to be updated, updating the appearance feature based on the user feedback.

In some embodiments, the method may further include sending the recommended parameter to a user.

In some embodiments, the recommended parameter may at least include a type, a size, and a depth of the feeding bowl for the feeding object.

In some embodiments, the recommendation model may include a first recommendation unit, a second recommendation unit, and a third recommendation unit, wherein the first recommendation unit is configured to determine the type of the feeding bowl based on the breed-specific feature, the second recommendation unit is configured to determine the size of the feeding bowl based on the body size feature and the type of the feeding bowl, and the third recommendation unit is configured to determine the depth of the feeding bowl based on the body proportion feature, and the type, and the size of the feeding bowl.

In some embodiments, the recommendation model may be generated by: obtaining a plurality of training samples, each of the plurality of training samples including sample breed-specific feature, sample body size feature, and sample body proportion feature of a sample feeding object and gold standard recommended parameters of a sample feeding bowl corresponding to the sample feeding object; generating the recommendation model by training an initial recommendation model including a preliminary first recommendation unit, a preliminary second recommendation unit, and a preliminary third recommendation unit using the plurality of training samples. In the training process, a predicted type of the sample feeding bowl output by the preliminary first recommendation unit may be input in the preliminary second recommendation unit with the sample body size feature, and the preliminary second recommendation unit may output a predicted size of the sample feeding bowl, and the predicted type and the predicted size of the sample feeding bowl may be input in the preliminary third recommendation unit with the sample body proportion feature, and the preliminary third recommendation unit may output a predicted depth of the sample feeding bowl.

In some embodiments, each of the plurality of training samples may further include at least one of a sample feeding feature and a sample growing feature of the sample feeding object.

In some embodiments, the body proportion feature may include a ratio of a nose length of the feeding object to a distance between the nose to the mouth of the feeding object, and the third recommendation unit may be further configured to determine the depth of the feeding bowl based on the ratio, and the type and the size of the feeding bowl.

According to another aspect of the present disclosure, a system for object feeding is provided. The system may include at least one storage device including a set of instructions; and at least one processor in communication with the at least one storage device. When executing the set of instructions, the at least one processor may be directed to perform operations. The operations may include obtaining a target image including a feeding object. The operations may include determining, based on the target image, an appearance feature of the feeding object. The appearance feature may at least include a breed-specific feature, a body size feature, and a body proportion feature. The operations may further include determining, based on the appearance feature of the feeding object, a recommended parameter relating to a feeding bowl for the feeding object through a recommendation model. The recommendation model may be a machine learning model.

According to still another aspect of the present disclosure, a non-transitory computer readable medium is provided. The non-transitory computer readable medium may include executable instructions that, when executed by at least one processor, direct the at least one processor to perform a method for object feeding. The method may include obtaining a target image including a feeding object. The method may include determining, based on the target image, an appearance feature of the feeding object. The appearance feature may at least include a breed-specific feature, a body size feature, and a body proportion feature. The method may further include determining, based on the appearance feature of the feeding object, a recommended parameter relating to a feeding bowl for the feeding object through a recommendation model. The recommendation model may be a machine learning model.

Additional features will be set forth in part in the description which follows, and in part will become apparent to those skilled in the art upon examination of the following and the accompanying drawings or may be learned by production or operation of the examples. The features of the present disclosure may be realized and attained by practice or use of various aspects of the methodologies, instrumentalities, and combinations set forth in the detailed examples discussed below.

### BRIEF DESCRIPTION OF THE DRAWINGS

The present disclosure is further described in terms of exemplary embodiments. These exemplary embodiments are described in detail with reference to the drawings. These embodiments are non-limiting exemplary embodiments, in which like reference numerals represent similar structures throughout the several views of the drawings, and wherein:

FIG. 1 is a schematic diagram illustrating an exemplary system for object feeding according to some embodiments of the present disclosure;

FIG. 2 is a block diagram illustrating an exemplary processing device according to some embodiments of the present disclosure;

FIG. 3 is a flowchart illustrating an exemplary process for object feeding according to some embodiments of the present disclosure;

FIG. 4 is a schematic diagram illustrating an exemplary process for determining an appearance feature of a feeding object using a feature determination model according to some embodiments of the present disclosure;

FIG. 5 is a schematic diagram illustrating an exemplary process for determining an appearance feature of a feeding object according to some embodiments of the present disclosure;

FIG. 6 is a schematic diagram illustrating an exemplary process for determining a breed-specific feature of a feeding object according to some embodiments of the present disclosure;

FIG. 7 is a schematic diagram illustrating an exemplary process for determining a body size feature of a feeding object according to some embodiments of the present disclosure;

FIG. 8 is a schematic diagram illustrating an exemplary process for updating an appearance feature of a feeding object according to some embodiments of the present disclosure;

FIG. 9A is a schematic diagram illustrating an exemplary process for determining a recommended parameter relating to a feeding bowl for a feeding object according to some embodiments of the present disclosure; and

FIG. 9B is a schematic diagram illustrating an exemplary process for determining a recommended parameter relating to a feeding bowl for a feeding object according to some embodiments of the present disclosure.

### DETAILED DESCRIPTION

In the following detailed description, numerous specific details are set forth by way of examples in order to provide a thorough understanding of the relevant disclosure. However, it should be apparent to those skilled in the art that the present disclosure may be practiced without such details. In other instances, well-known methods, procedures, systems, components, and/or circuitry have been described at a relatively high level, without detail, in order to avoid unnecessarily obscuring aspects of the present disclosure. Various modifications to the disclosed embodiments will be readily apparent to those skilled in the art, and the general principles defined herein may be applied to other embodiments and applications without departing from the spirit and scope of the present disclosure. Thus, the present disclosure is not limited to the embodiments shown, but to be accorded the widest scope consistent with the claims.

The terminology used herein is for the purpose of describing particular example embodiments only and is not intended to be limiting. As used herein, the singular forms “a,” “an,” and “the” may be intended to include the plural forms as well, unless the context clearly indicates otherwise. It will be further understood that the terms “comprise,” “comprises,” and/or “comprising,” “include,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that when a unit, engine, module, or block is referred to as being “on,” “connected to,” or “coupled to,” another unit, engine, module, or block, it may be directly on, connected or coupled to, or communicate with the other unit, engine, module, or block, or an intervening unit, engine, module, or block may be present, unless the context clearly indicates otherwise. As used herein, the term “and/or” includes any and all combinations of one or more of the associated listed items.

These and other features, and characteristics of the present disclosure, as well as the methods of operation and functions of the related elements of structure and the combination of parts and economies of manufacture, may become more apparent upon consideration of the following description with reference to the accompanying drawings, all of which form a part of this disclosure. It is to be expressly understood, however, that the drawings are for the purpose of illustration and description only and are not intended to limit the scope of the present disclosure. It is understood that the drawings are not to scale.

The flowcharts used in the present disclosure illustrate operations that systems implement according to some embodiments of the present disclosure. It is to be expressly understood, the operations of the flowcharts may be implemented not in order. Conversely, the operations may be implemented in an inverted order, or simultaneously. Moreover, one or more other operations may be added to the flowcharts. One or more operations may be removed from the flowcharts.

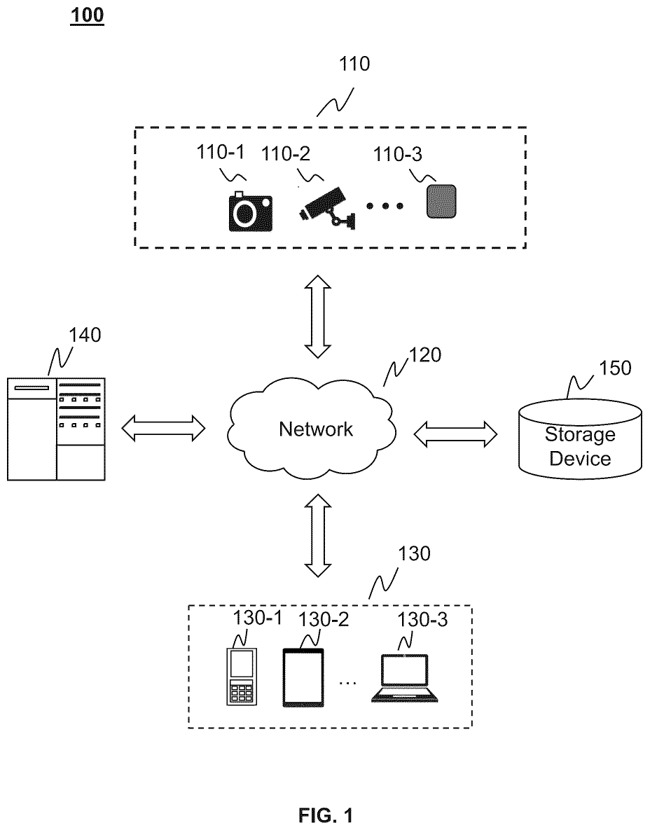

FIG. 1 is a schematic diagram illustrating an exemplary system 100 for object feeding according to some embodiments of the present disclosure. As shown in FIG. 1, the system 100 may include an image acquisition device 110, a network 120, at least one terminal device 130, a processing device 140, and a storage device 150.

The image acquisition device 110 may be configured to acquire a target image including a feeding object or at least a part of the feeding object. The feeding object refers to a subject that is fed through a feeding bowl. The feeding bowl may be placed in homes, pet stores, zoos, farms, wildlife shelters, stray animal care facilities, and other locations. The feeding object may include dogs, cats, rats, rabbits, birds, anteaters, hedgehogs, cows, horses, sheep, or the like, or any combination thereof.

It should be noted that the above descriptions of the feeding object are provided for the purposes of illustration, and are not intended to limit the scope of the present disclosure.

In some embodiments, the image acquisition device 110 may include a camera 110-1, a video recorder 110-2, an image sensor 110-3, etc. The camera 110-1 may include a gun camera, a dome camera, an integrated camera, a monocular camera, a binocular camera, a multi-view camera, a visible light camera, a thermal imaging camera, or the like, or any combination thereof. The video recorder 110-2 may include a PC Digital Video Recorder (DVR), an embedded DVR, a visible light DVR, a thermal imaging DVR, or the like, or any combination thereof. The image sensor 110-3 may include a charge coupled device (CCD) image sensor, a complementary metal oxide semiconductor (CMOS) image sensor, or the like, or any combination thereof. In some embodiments, the image acquisition device 110 may include a plurality of components each of which can acquire an image. For example, the image acquisition device 110 may include a first imaging component and a second imaging component that can acquire multiple target images from different shooting angles. In some embodiments, the image acquisition device 110 may transmit the acquired image(s) to one or more components (e.g., the at least one terminal device 130, the processing device 140, the storage device 150) of the system 100 via the network 120. In some embodiments, the image acquisition device 110 may be integrated into the at least one terminal device 130.

The network 120 may include any suitable network that can facilitate the exchange of information and/or data for the system 100. In some embodiments, one or more components (e.g., the image acquisition device 110, the at least one terminal device 130, the processing device 140, the storage device 150, etc.) of the system 100 may communicate information and/or data with one or more other components of the system 100 via the network 120. For example, the processing device 140 may obtain the target image from the image acquisition device 110 via the network 120. As another example, the processing device 140 may obtain user instructions from the at least one terminal device 130 via the network 120. In some embodiments, the network 120 may include one or more network access points.

The at least one terminal device 130 may include a mobile device 130-1, a tablet computer 130-2, a laptop computer 130-3, or the like, or any combination thereof. In some embodiments, the mobile device 130-1 may include a smart home device, a wearable device, a mobile device, a virtual reality device, an augmented reality device, or the like, or any combination thereof. In some embodiments, the at least one terminal device 130 may include a processing unit, a display unit, a sensing unit, an input/output (I/O) unit, a storage unit, etc. In some embodiments, the display unit may include an interactive interface that is configured to receive an input from a user. In some embodiments, the at least one terminal device 130 may be part of the processing device 140.

The processing device 140 may process data and/or information obtained from one or more components (the image acquisition device 110, the at least one terminal device 130, and/or the storage device 150) of the system 100. For example, the processing device 140 may obtain the target image including the feeding object. As another example, the processing device 140 may determine an appearance feature of the feeding object based on the target image. As still another example, the processing device 140 may determine a recommended parameter relating to the feeding bowl for the feeding object based on the appearance feature of the feeding object. As still another example, the processing device 140 may update the recommended parameter based on another feature (e.g., a feeding feature, a growing feature, etc.) of the feeding object. In some embodiments, the processing device 140 may be a single server or a server group. The server group may be centralized or distributed. In some embodiments, the processing device 140 may be local or remote. In some embodiments, the processing device 140 may be implemented on a cloud platform. For example, the cloud platform includes a private cloud, a public cloud, a hybrid cloud, a community cloud, a distributed cloud, an inter-cloud, a multi-cloud, or the like, or any combination thereof.

In some embodiments, the processing device 140 may be implemented by a computing device. For example, the computing device may include a processor, a storage, an input/output (I/O), and a communication port. The processor may execute computer instructions (e.g., program codes) and perform functions of the processing device 140 in accordance with the techniques described herein. The computer instructions may include, for example, routines, programs, objects, components, data structures, procedures, modules, and functions, which perform particular functions described herein. In some embodiments, the processing device 140, or a portion of the processing device 140 may be implemented by a portion of the at least one terminal device 130.

The storage device 150 may store data/information obtained from the image acquisition device 110, the at least one terminal device 130, and/or any other component of the system 100. In some embodiments, the storage device 150 may include a mass storage, a removable storage, a volatile read-and-write memory, a read-only memory (ROM), or the like, or any combination thereof. In some embodiments, the storage device 150 may store one or more programs and/or instructions to perform exemplary methods described in the present disclosure.

In some embodiments, the storage device 150 may be connected to the network 120 to communicate with one or more other components in the system 100 (e.g., the processing device 140, the at least one terminal device 130, etc.). In some embodiments, the storage device 150 may be part of the processing device 140.

In some embodiments, the system 100 may include one or more additional components and/or one or more components of the system 100 described above may be omitted. Additionally or alternatively, two or more components of the system 100 may be integrated into a single component. A component of the system 100 may be implemented on two or more sub-components.

It should be noted that the foregoing descriptions are merely provided for the purpose of illustration and are not intended to limit the scope of the present disclosure. For those skilled in the art, amendments and variations may be made under the teaching of the descriptions of the present disclosure. The features, structures, methods, and other characteristics of the exemplary embodiments described in the present disclosure may be combined in various manners to obtain additional and/or alternative exemplary embodiments. For example, multiple components of the system 100 may be integrated into one device. For instance, the processing device 140 and/or the storage device 150 may be integrated into the at least one terminal device 130. As another example, the system 100 may be implemented on other devices to achieve similar or different functions. However, these amendments and variations do not depart from the scope of the present disclosure.

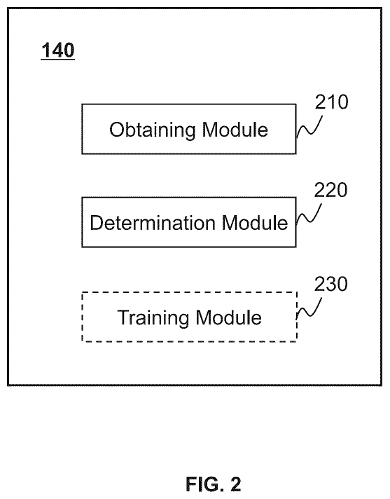

FIG. 2 is a block diagram illustrating an exemplary processing device 140 according to some embodiments of the present disclosure. The modules illustrated in FIG. 2 may be implemented on the processing device 140. In some embodiments, the processing device 140 may be in communication with a computer-readable storage medium (e.g., the storage device 150 illustrated in FIG. 1) and execute instructions stored in the computer-readable storage medium. The processing device 140 may include an obtaining module 210 and a determination module 220.

The obtaining module 210 may be configured to obtain a target image including a feeding object. More descriptions regarding the obtaining of the target image may be found elsewhere in the present disclosure. See, e.g., operation 302 and relevant descriptions thereof.

The determination module 220 may be configured to determine an appearance feature of the feeding object based on the target image. The appearance feature may include a breed-specific feature, a body size feature, a body proportion feature, or the like, or any combination thereof. More descriptions regarding the determination of the appearance feature of the feeding object may be found elsewhere in the present disclosure. See, e.g., operation 304 and relevant descriptions thereof.

The determination module 220 may be further configured to determine a recommended parameter relating to a feeding bowl for the feeding object based on the appearance feature of the feeding object through a recommendation model. The recommendation model may be a trained machine learning model. More descriptions regarding the determination of the recommended parameter may be found elsewhere in the present disclosure. See, e.g., operation 306 and relevant descriptions thereof.

In some embodiments, the processing device 140 may further include a training module 230. The training module 230 may be configured to generate one or more machine learning models, such as, the recommendation model, a feature determination model, a breed recognition model, etc. In some embodiments, the training module 230 may be implemented on the processing device 140 or a processing device other than the processing device 140. In some embodiments, the training module 230 and other modules (e.g., the obtaining module 210, the determination module 220) may be implemented on a same processing device (e.g., the processing device 140). Alternatively, the training module 230 and other modules (e.g., the obtaining module 210 and/or the determination module 220) may be implemented on different processing devices. For example, the training module 230 may be implemented on a processing device of a vendor of the machine learning model(s), while the other modules may be implemented on a processing device of a user of the machine learning model(s).

It should be noted that the above descriptions of the processing device 140 are provided for the purposes of illustration, and are not intended to limit the scope of the present disclosure. For persons having ordinary skills in the art, various variations and modifications may be conducted under the guidance of the present disclosure. However, those variations and modifications do not depart from the scope of the present disclosure. In some embodiments, the processing device 140 may include one or more other modules. For example, the processing device 140 may include a storage module to store data generated by the modules in the processing device 140. In some embodiments, any two of the modules may be combined as a single module, and any one of the modules may be divided into two or more units.

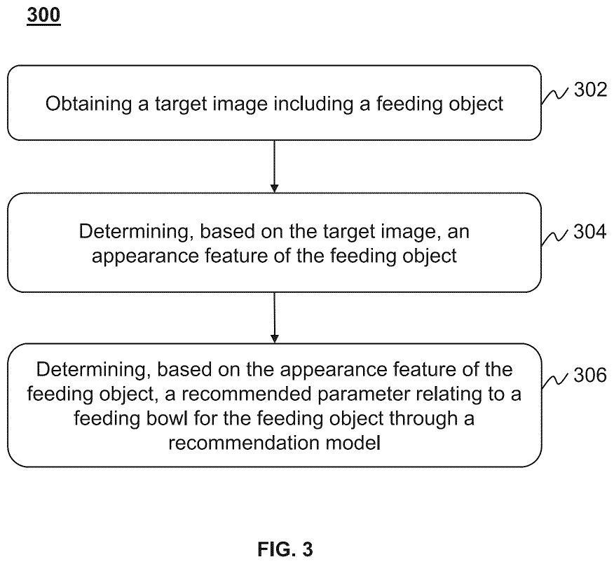

FIG. 3 is a flowchart illustrating an exemplary process 300 for object feeding according to some embodiments of the present disclosure. The process 300 may be implemented in the system 100 illustrated in FIG. 1. For example, the process 300 may be stored in the storage device 150 in the form of instructions (e.g., an application), and invoked and/or executed by the processing device 140.

In 302, the processing device 140 (e.g., the obtaining module 210) may obtain a target image including a feeding object.

The feeding object refers to a subject that is fed through a feeding bowl. More descriptions regarding the feeding object may be found elsewhere in the present disclosure. See, e.g., FIG. 1 and relevant descriptions thereof.

The target image may indicate an overall outline and/or a local detail of the feeding object. A shooting angle of the image may include a frontal view, a side view, a top view, or the like, or any combination thereof. A posture of the feeding object in the image may include a lying posture, a standing posture, a jumping posture, a running posture, a sitting posture, or the like, or any combination thereof.

In some embodiments, the target image may include multiple target images, and at least a portion of the multiple target images may be different. For example, shooting angles of the multiple target images may be different. As another example, postures of the feeding object in the multiple target images may be different. As still another example, parts of the feeding object in the multiple target images may be different. As yet another example, the multiple target images may be captured at different times. Merely by way of example, the target image may include an image 1, an image 2, an image 3, and an image 4 including the feeding object. The image 1 may be captured from the frontal view when the feeding object is in a standing posture, and the image 1 may include the overall outline of the feeding object. The image 2 may be captured from the top view when the feeding object is in a lying posture, and the image 2 may include the overall outline of the feeding object. The image 3 may be captured from the frontal view, and the image 3 may include a close-up of the face of the feeding object. The image 4 may be captured from the side view when the feeding object is in a standing posture, and the image 4 may include the side face, neck, part of the back, forelimbs, etc., of the feeding object (e.g., a pet dog).

In some embodiments, the processing device 140 may obtain the target image including the feeding object from the image acquisition device 110, the at least one terminal device 130, or a storage device (e.g., the storage device 150, a database, an external storage, etc.). For example, the processing device 140 may obtain the target image by identifying the feeding object from images stored in the at least one terminal device 130 through an object identification algorithm and determine image(s) including the feeding object as the target image.

In some embodiments, after the target image is obtained, the processing device 140 may perform a preprocessing operation (e.g., target region segmentation, dimension adjustment, image normalization, etc.) on the target image. The processing device 140 may further perform other operations of the process 300 on the preprocessed target image. For purposes of illustration, the target image is taken as an example for describing the execution process of the process 300.

In 304, the processing device 140 (e.g., the determination module 220) may determine an appearance feature of the feeding object based on the target image.

The appearance feature may include a breed-specific feature, a body size feature, a body proportion feature, or the like, or any combination thereof.

The breed-specific feature refers to a feature relating to the bread. The breed refers to a group within the same species with similar genetic characteristics and appearance. For example, dog breeds may include Labrador Retriever, German Shepherd, Golden Retriever, French Bulldog, Bichon Frise, Poodle, Shih Tzu, West Highland White Terrier, Husky, Beagle, Chihuahua, Border Collie, Jack Russell Terrier, Schnauzer, Dalmatian, or the like, or any combination thereof. As another example, cat breeds include Persian Cat, Siamese Cat, British Shorthair, Maine Coon, Sphynx Cat, Ragdoll Cat, Chinchilla Cat, Russian Blue Cat, Abyssinian Cat, Norwegian Forest Cat, Chinchilla Cat, Turkish Angora, Scottish Fold, Egyptian Cat, Oriental Shorthair, or the like, or any combination thereof.

In some embodiments, the breed-specific feature may be determined by genetics, and differences of the breed-specific feature between individuals of the same breed may be small. For example, the breed-specific feature may include a breed type, a height of the mouth, a shape of the snout, a length of the snout, a size of the head, a skeleton structure, an angle of the neck relative to the ground, a length of a whisker, a distance between the mouth and the nose, a distance between the mouth and the ears, or the like, or any combination thereof.

The body size feature refers to a size attribute relating to an individual. For example, the body size feature may be determined by genetics, environment, nutrition, evolutionary adaptations, etc., regarding the feeding object, and differences of the body size feature between individuals of the same breed may be large. Exemplary body size features may include a length (e.g., a length from head to tail, a limb length), a height (e.g., a height at the shoulder), a width, a weight, a chest girth, or the like, or any combination thereof.

The body proportion feature (also referred to as a body morphology feature) refers to relative proportions of different body parts relating to an individual. In some embodiments, the body proportion feature may indicate the overall morphological structure of the feeding object. For example, two dogs may have the same length from head to tail, but the first dog may have a longer neck and a shorter body, and the second dog may have a shorter neck and a longer body. Therefore, the two dogs may have different body proportion features. Exemplary body proportion features may include a muscle distribution, a body fat level, a ratio of a nose length of the feeding object to a distance between the nose to the mouth of the feeding object, a ratio of the length from head to tail to the limb length, a waist-to-hip ratio, a body proportion classification, or the like, or any combination thereof.

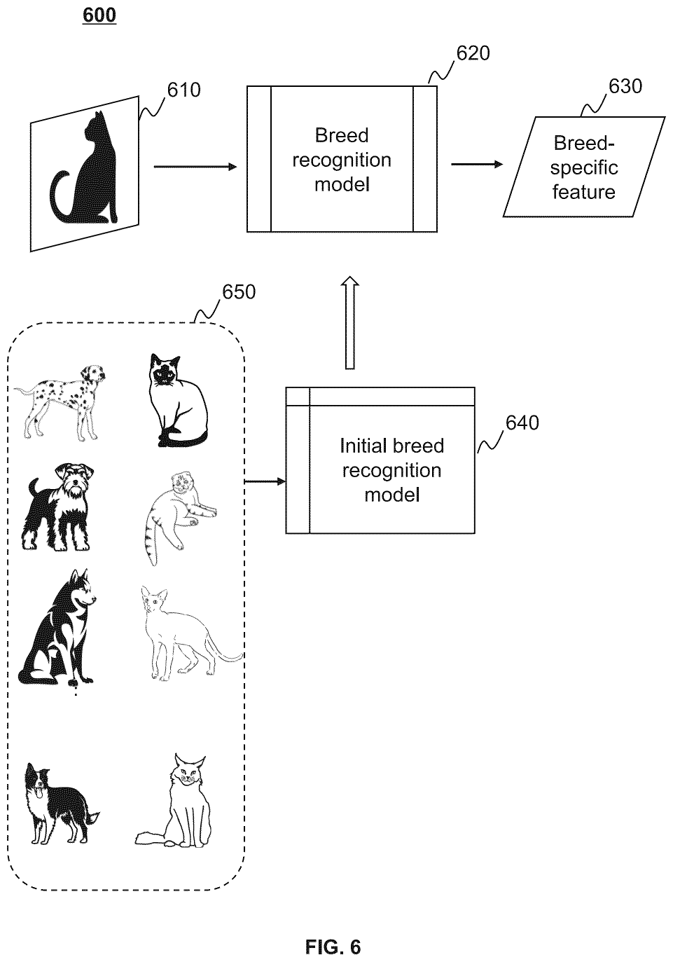

In some embodiments, the processing device 140 may determine the appearance feature of the feeding object based on the target image. For example, the processing device 140 may determine the breed-specific feature and the body size feature of the feeding object based on the target image, and determine the body proportion feature of the feeding object based on the breed-specific feature and the body size feature of the feeding object. More descriptions regarding the determination of the appearance feature of the feeding object may be found elsewhere in the present disclosure. See, e.g., FIG. 5 and relevant descriptions thereof.

In some embodiments, the processing device 140 may determine the appearance feature of the feeding object by inputting the target image into a feature determination model. For example, the processing device 140 may input the target image into the feature determination model, and the feature determination model may output the appearance feature. In some embodiments, if there are multiple types of appearance features, some appearance features may be determined through the feature determination model while other appearance features may be determined in another manner. For example, the breed-specific feature may be determined through the feature determination model (also referred to as a breed recognition model), but the body size feature and the body proportion feature may be determined through an image identification algorithm.

In some embodiments, the feature determination model refers to a process or an algorithm for determining the appearance feature based on the target image. For example, the feature determination model may indicate a mapping relationship between the target image of the feeding object and the appearance feature of the feeding object. The feature determination model may be a trained machine learning model.

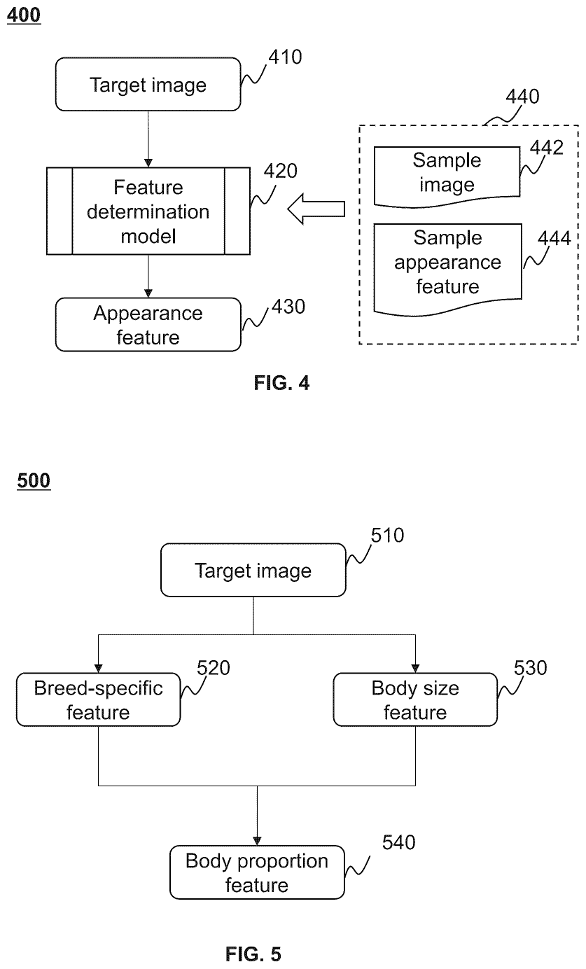

In some embodiments, the processing device 140 may obtain the feature determination model from a storage device (e.g., the storage device 150) of the system 100 or a third-party database. In some embodiments, the feature determination model may be generated by the processing device 140 (e.g., the training module 230) or another computing device according to a machine learning algorithm. In some embodiments, the feature determination model may be generated by a computing device (e.g., the processing device 140) by performing process 400 as described in connection with FIG. 4.

In some embodiments, the target image may include the multiple target images, and the processing device 140 may construct a three-dimensional (3D) model of the feeding object based on the multiple target images and determine the appearance feature of the feeding object based on the 3D model of the feeding object. For example, the processing device 140 may construct the 3D model of the feeding object by processing the multiple target images through an image processing algorithm. Exemplary image processing algorithms may include a structure from motion (SFM) algorithm, a multi-view stereo (MVS) algorithm, a machine learning algorithm, a voxel prediction algorithm, a meshing algorithm (e.g., a Pixel2Mesh algorithm, a Mesh R-CNN model), a template-based algorithm, or the like, or any combination thereof. As another example, the processing device 140 may screen the multiple target images for removing blurred and/or incomplete images, and construct the 3D model of the feeding object by processing the screened images. Therefore, the quality of the images for constructing the 3D model can be improved, thereby improving the accuracy of the 3D model and the determination of the appearance feature of the feeding object.

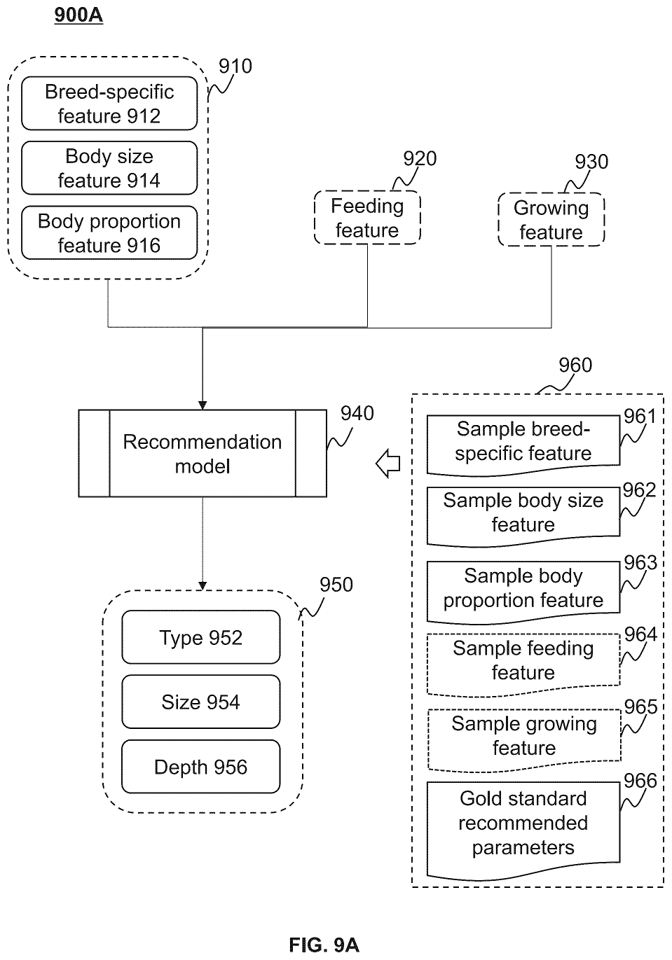

In some embodiments, the processing device 140 may direct the user to check the appearance feature of the feeding object. For example, the processing device 140 may send the appearance feature of the feeding object to the user, and receive user feedback on the appearance feature of the feeding object. If the user feedback indicates the appearance feature needs to be updated, the processing device 140 may update the appearance feature based on the user feedback. If the user feedback indicates the appearance feature does not need to be updated, the processing device 140 may proceed to operation 306. More descriptions regarding the update of the appearance feature of the feeding object may be found elsewhere in the present disclosure. See, e.g., FIG. 8 and relevant descriptions thereof.

In 306, the processing device 140 (e.g., the determination module 220) may determine a recommended parameter relating to the feeding bowl for the feeding object based on the appearance feature of the feeding object through a recommendation model.

The feeding bowl refers to any item used to feed or provide food and/or water to the feeding object.

The recommended parameter may include a type, a size, a depth, a thickness, a tilt angle, a material, or the like, or any combination thereof, of the feeding bowl for the feeding object. In some embodiments, the recommended parameter may further include whether the feeding bowl needs a support and a recommended parameter of the support (also referred to as a second recommended parameter). For example, the second recommended parameter may include a type, a size, a height, a material, or the like, or any combination thereof, of the support (e.g., a stand).

In some embodiments, the processing device 140 may determine the recommended parameter relating to the feeding bowl by inputting the appearance feature into the recommendation model. For example, the processing device 140 may input the appearance feature into the recommendation model, and the recommendation model may output the recommended parameter.

In some embodiments, the recommendation model refers to a process or an algorithm for determining the recommended parameter based on the appearance feature. For example, the recommendation model may indicate a mapping relationship between the recommendation relating to the feeding bowl for the feeding object and the appearance feature of the feeding object. The recommendation model may be a trained machine learning model.

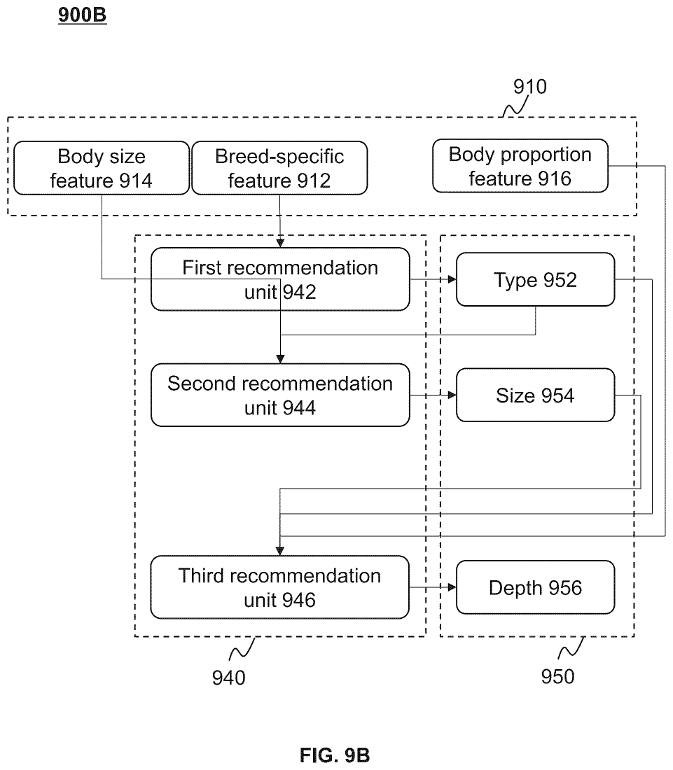

In some embodiments, the processing device 140 may obtain the recommendation model from a storage device (e.g., the storage device 150) of the system 100 or a third-party database. In some embodiments, the recommendation model may be generated by the processing device 140 (e.g., the training module 230) or another computing device according to a machine learning algorithm. In some embodiments, the recommendation model may be generated by a computing device (e.g., the processing device 140) by performing process 900A as described in connection with FIG. 9A.

It should be noted that the recommendation model is merely provided for illustration purposes, and can be modified according to an actual need. For example, the target image may be input into the recommendation model with the appearance feature to determine the recommended parameter for the feeding object. As another example, the recommendation model may include a first recommendation unit, a second recommendation unit, and a third recommendation unit. The first recommendation unit may be configured to determine the type of the feeding bowl based on the breed-specific feature, the second recommendation unit may be configured to determine the size of the feeding bowl based on the body size feature and the type of the feeding bowl, and the third recommendation unit may be configured to determine the depth of the feeding bowl based on the body proportion feature, and the type and the size of the feeding bowl. More descriptions regarding the generation of the recommended parameter using the recommendation model may be found elsewhere in the present disclosure. See, e.g., FIGS. 9A and 9B and relevant descriptions thereof.

In some embodiments, the processing device 140 may determine the recommended parameter relating to the feeding bowl for the feeding object further based on a feeding feature and/or a growing feature of the feeding object.

For example, the processing device 140 may obtain a feeding feature of the feeding object, and determine an adjustment coefficient (also referred to as a first adjustment coefficient) of the recommended parameter based on the feeding feature. Further, the processing device 140 may adjust the recommended parameter based on the adjustment coefficient.

The feeding feature may relate to the feeding requirements, eating habits, and feeding behaviors of the feeding object. Exemplary feeding features of the feeding object may include a feeding frequency, a feeding preference, a feeding time, a feeding intake, a feeding manner, whether the front limb assists the feeding, a motion range of the mouth during the feeding, a motion range of the whisker during the feeding, or the like, or any combination thereof. In some embodiments, the feeding feature of the feeding object may be input by a user (e.g., a feeder of the feeding object). Alternatively, the feeding feature of the feeding object may be automatically determined based on records of the feeding object, e.g., through a feature extraction algorithm.

The first adjustment coefficient is used to adjust the recommended parameter based on the feeding feature. For example, when the feeding feature and the recommended parameter are positively correlated, the first adjustment coefficient may be a value larger than 1. Otherwise, the first adjustment coefficient may be a value larger than 0 and less than 1. Merely by way of example, if the feeding intake of the feeding object is relatively large, the first adjustment coefficient corresponding to the size of the feeding bowl may be relatively large.

In some embodiments, the processing device 140 may determine the first adjustment coefficient automatically. For example, the processing device 140 may predetermine a corresponding relationship (e.g., a table) between candidate first adjustment coefficients and candidate feeding features, and determine the first adjustment coefficient based on the corresponding relationship and the feeding feature, such as, by looking up the table. In some embodiments, the first adjustment coefficient may be set by the user.

In some embodiments, the processing device 140 may adjust the recommended parameter based on the first adjustment coefficient. For example, the processing device 140 may multiply the recommended parameter with the first adjustment coefficient.

As another example, the processing device 140 may obtain the growing feature of the feeding object, and determine an adjustment coefficient (also referred to as a second adjustment coefficient) of the recommended parameter based on the growing feature. Further, the processing device 140 may adjust the recommended parameter based on the second adjustment coefficient.

The growing feature may indicate whether the feeding object is in a growing stage. In some embodiments, the growing feature of the feeding object may be input by the user. For example, the user may input the age of the feeding object, and the processing device 140 may determine the growing feature based on the age of the feeding object. For instance, if the age of the feeding object is less than 1 year, the processing device 140 may determine that the feeding object is in the growing stage. Otherwise, the processing device 140 may determine that the feeding object is beyond the growing stage. As another example, the processing device 140 may determine the growing feature based on body size features of the feeding object at different times. For instance, the processing device 140 may determine a first difference between a current body size feature of the feeding object and a general body size feature of the breed of the feeding object. If the difference is larger than a first difference threshold (e.g., 5 centimeters, 10 centimeters, etc.), the processing device 140 may obtain historical body size features of the feeding object in a historical time period (e.g., one month, two months, etc.), and determine whether a second difference between the current body size feature and the historical body size features of the feeding object is larger than a second difference threshold (e.g., 5 centimeters, 10 centimeters, etc.). If the second difference is larger than the second difference threshold, the processing device 140 may determine that the feeding object is in the growing stage. Otherwise, the processing device 140 may determine that the feeding object is beyond the growing stage, and the feeding object is a dwarf type or a giant type. As still another example, the processing device 140 may automatically determine the growing feature based on multiple target images captured at different times (e.g., by analyzing the change of the body size feature of the feeding object over time).

The second adjustment coefficient is used to adjust the recommended parameter based on the growing feature. In some embodiments, the second adjustment coefficient may be determined in a similar manner as how the first adjustment coefficient is determined as described above, and the recommended parameter may be adjusted based on the second adjustment coefficient in a similar manner as how the recommended parameter is adjusted based on the first adjustment coefficient as described above, which are not repeated.

In some embodiments, the processing device 140 may adjust the recommended parameter based on the first adjustment coefficient and the second adjustment coefficient.

In some embodiments, if the feeding object is in the growing stage, the processing device 140 may predict variations of the appearance feature, and predict the recommended parameter based on the variations of the appearance feature.

In some embodiments, the feeding feature and/or the growing feature of the feeding object may be input into the recommendation model with the appearance feature. For example, the processing device 140 may determine the recommended parameter for the feeding object by inputting the appearance feature and the feeding feature of the feeding object into the recommendation model. As another example, the processing device 140 may determine the recommended parameter for the feeding object by inputting the appearance feature and the growing feature of the feeding object into the recommendation model.

In some embodiments, the processing device 140 may further determine a second recommended parameter relating to another feeding item for the feeding object based on the appearance feature of the feeding object. For example, the processing device 140 may determine the second recommended parameter relating to collars, clothing, etc., of the feeding object based on the appearance feature of the feeding object.

In some embodiments, the processing device 140 may send the recommended parameter to the user. For example, the processing device 140 may send the recommended parameter to the at least one terminal device 130, and direct a display of the at least one terminal device 130 to display the recommended parameter. As another example, the processing device 140 may send the recommended parameter to the user via email, text message, instant messaging applications (e.g., WhatsApp, WeChat, etc.), service push notifications, etc.

According to some embodiments of the present disclosure, by introducing the recommendation model, the recommended parameter relating to the feeding bowl for the feeding object can be automatically determined based on the appearance feature of the feeding object, and the recommended feeding bowl can meet the individual needs of the feeding object, thereby improving the efficiency and accuracy of the determination of the feeding bowl, and enhancing the dining experience of the feeding object.

FIG. 4 is a schematic diagram illustrating an exemplary process 400 for determining an appearance feature of a feeding object using a feature determination model according to some embodiments of the present disclosure.

As illustrated in FIG. 4, in some embodiments, a target image 410 including a feeding object may be input into a feature determination model 420, and the feature determination model 420 may output an appearance feature 430 of the feeding object.

The feature determination model 420 refers to a process or an algorithm for determining the appearance feature 430 of the feeding object based on the target image 410 of the feeding object. In some embodiments, the feature determination model 420 may be a trained machine learning model. For example, the feature determination model 420 may include a convolutional neural network (CNN), a deep neural network (DNN), a recurrent neural network (RNN), a long short term memory (LSTM) network model, a fully convolutional neural network (FCN) model, a generative adversarial network (GAN) model, a radial basis function (RBF) machine learning model, a DeepMask model, a SegNet model, a dilated convolution model, a conditional random fields as recurrent neural networks (CRFasRNN) model, a pyramid scene parsing network (pspnet) model, or the like, or any combination thereof.

In some embodiments, the feature determination model 420 may be obtained by training an initial feature determination model based on a plurality of training samples 440 (also referred to as first training samples). In some embodiments, each of the plurality of training samples 440 may include a sample image 442 of a sample feeding object as an input of the initial feature determination model, and a sample appearance feature 444 of the sample feeding object as a label.

The obtaining of the sample image 442 may be similar to the obtaining of the target image described in operation 302. The sample appearance feature 444 may be determined automatically or manually. For example, a user (e.g., a feeder) may determine the sample appearance feature 444 based on the sample image 442. As another example, the sample appearance feature 444 may be determined based on merchant recommendations and/or sales records. In some embodiments, the processing device 140 may obtain the plurality of training samples 440 by retrieving (e.g., through a data interface) a database or a storage device.

During the training of the initial feature determination model, the plurality of training samples 440 may be input into the initial feature determination model, and parameter(s) of the initial feature determination model may be updated through one or more iterations. For example, the processing device 140 may input the sample image 442 of each first training sample into the initial feature determination model, and obtain a first prediction result. The processing device 140 may determine a loss function (also referred to as a first loss function) based on the first prediction result and the label (i.e., the corresponding sample appearance feature 444) of each training sample. The loss function may be associated with a difference between the first prediction result and the label. The processing device 140 may adjust the parameter(s) of the initial feature determination model based on the loss function to reduce the difference between the first prediction result and the label, for example, by continuously adjusting the parameter(s) of the initial feature determination model to reduce or minimize the loss function.

In some embodiments, the loss function may be a perceptual loss function, a squared loss function, an exponential loss function, a logistic regression loss function, a quadratic loss function, etc.

In some embodiments, the feature determination model 420 may also be obtained according to other training manners. For example, the feature determination model 420 may be obtained based on an initial learning rate (e.g., 0.1) and/or an attenuation strategy using the plurality of training samples 440.

By using the feature determination model, the appearance feature of the feeding object can be determined automatically, which can reduce manual intervention, thereby improving the efficiency and accuracy of the determination of the appearance feature of the feeding object.

FIG. 5 is a schematic diagram illustrating an exemplary process 500 for determining an appearance feature of a feeding object according to some embodiments of the present disclosure.

As illustrated in FIG. 5, in some embodiments, a breed-specific feature 520 and a body size feature 530 of a feeding object may be determined based on a target image 510 of the feeding object, and a body proportion feature 540 of the feeding object may be determined based on the breed-specific feature 520 and the body size feature 530 of the feeding object.

In some embodiments, the processing device 140 may determine the breed-specific feature 520 (e.g., the breed type) of the feeding object based on the target image 510 in various manners. For example, the processing device 140 may identify the feeding object from the target image 510 using a pre-trained object detection model (e.g., a You Only Look Once (YOLO) model, a Faster R-CNN model, etc.), and determine the breed-specific feature 520 based on the identified feeding object. As another example, the processing device 140 may extract the breed-specific feature 520 of the feeding object from the target image 510 using computer vision technology, and determine the breed of the feeding object based on the extracted feature. As still another example, the processing device 140 may compare known images of known breeds in a database with the target image 510 to determine a known image with the highest similarity to the target image 510 using an image matching technique, thereby determining the breed-specific feature 520 of the feeding object based on the known image with the highest similarity.

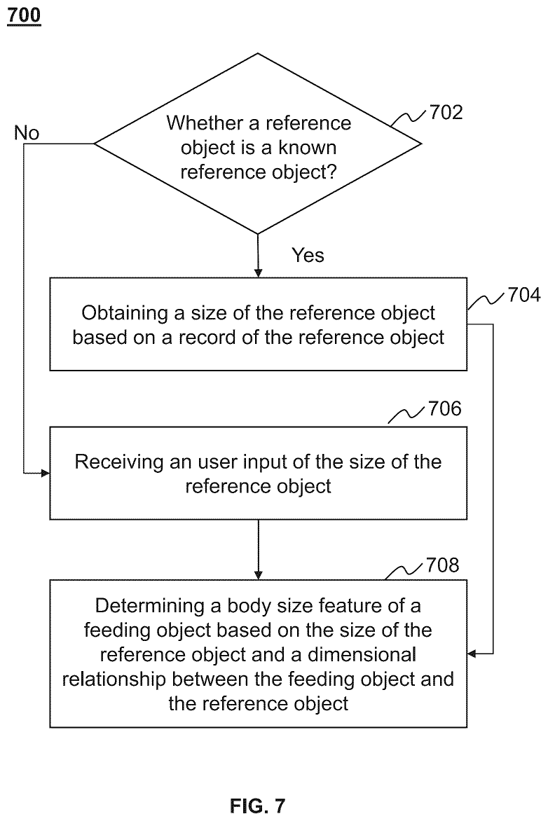

In some embodiments, the processing device 140 may determine the breed-specific feature 520 of the feeding object based on a breed recognition model and the target image 510. For example, the processing device 140 may determine the breed-specific feature 520 of the feeding object by inputting the target image 510 into the breed recognition model. The breed recognition model may be a trained machine learning model. More descriptions regarding the breed recognition model may be found elsewhere in the present disclosure. See, e.g., FIG. 6 and relevant descriptions thereof.

In some embodiments, the processing device 140 may determine the body size feature 530 of the feeding object based on the target image 510 in various manners. For example, the processing device 140 may identify the feeding object from the target image 510 using the pre-trained object detection model, obtain boundary information of the feeding object, and determine (e.g., estimate) the body size feature 530 of the feeding object based on the boundary information.

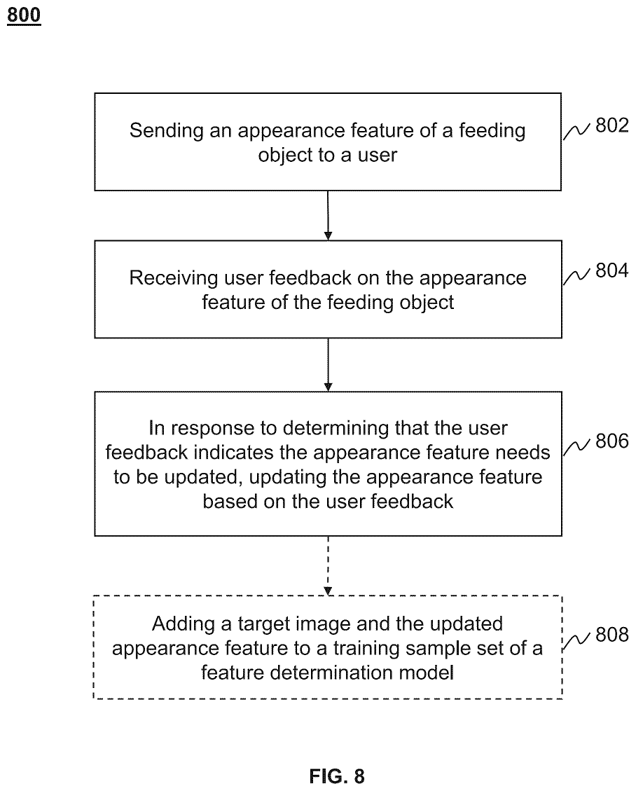

In some embodiments, the target image 510 may include a reference object. The processing device 140 may obtain a size of the reference object, and determine the body size feature 530 of the feeding object based on the size of the reference object and a dimensional relationship between the feeding object and the reference object. The reference object refers to an object used as a benchmark or standard. The target image may include other objects, such as feeding bowls, water bowls, toys, mats, climbing frames, traction tools, bathing supplies, furniture, etc. In some embodiments, the processing device 140 may designate at least one of the other objects as the reference object. For example, the processing device 140 may determine whether the reference object is a known reference object. If the reference object is a known reference object, the processing device 140 may obtain the size of the reference object based on a record of the reference object. If the reference object is not a known reference object, the processing device 140 may receive a user input of the size of the reference object. After the size of the reference object is obtained, the processing device 140 may determine the body size feature 530 of the feeding object based on the size of the reference object and the dimensional relationship between the feeding object and the reference object. More descriptions regarding the determination of the body size feature may be found elsewhere in the present disclosure. See, e.g., FIG. 7 and relevant descriptions thereof.

In some embodiments, the processing device 140 may obtain imaging information relating to the target image 510, and determine the body size feature 530 of the feeding object based on the target image 510 and the imaging information relating to the target image 510. The imaging information may at least include parametric information of an image acquisition device (e.g., the image acquisition device 110) used for collecting the target image 510. Exemplary parametric information may include a focal length, a sensor size, a shooting distance, a shooting angle, an image distance, or the like, or any combination thereof. For example, the processing device 140 may obtain the imaging information from the image acquisition device 110, the at least one terminal device 130, or a storage device (e.g., the storage device 150, a database, an external storage, etc.). In some embodiments, the processing device 140 may determine the body size feature 530 of the feeding object based on the target image 510 and the imaging information relating to the target image 510 through a geometric perspective transformation relationship (e.g., a transformation matrix). In some embodiments, the processing device 140 may determine the body size feature 530 of the feeding object based on the target image 510 and the imaging information relating to the target image 510 through a machine-learning algorithm.

In some embodiments, the processing device 140 may retrieve the body proportion feature 540 of the feeding object from a feeding object database based on the breed-specific feature 520 and the body size feature 530 of the feeding object. The feeding object database may be constructed based on appearance data of reference feeding objects of a plurality of breeds. For example, the processing device 140 may determine a key feature value of the feeding object based on the body size feature 530 of the feeding object, and retrieve the body proportion feature 540 of the feeding object from the feeding object database by matching the key feature value and the breed-specific feature 520 of the feeding object with candidate body proportion features in the feeding object database. As another example, the processing device 140 may use a database query language (e.g., a structured query language (SQL)) or other query tools to retrieve the body proportion feature 540 of the feeding object from the feeding object database based on the breed-specific feature 520 and the body size feature 530 of the feeding object.

In some embodiments, the candidate body proportion features in the feeding object database may be determined based on the appearance data of the reference feeding objects. Merely by way of example, for a breed of Husky in the feeding object database, appearance data of reference Huskies may be used to determine that the candidate body proportion features of Husky include a slender type, a standard type, a muscular type, and a super-heavy type and the corresponding key feature value (e.g., a weight) of each of the four types. When a weight (i.e., the key feature value) of the feeding object (e.g., a Husky) is obtained, the processing device 140 may determine the body proportion feature of the Husky from the feeding object database by matching the weight of the Husky with the four types and the corresponding key feature values in the feeding object database.

By constructing the feeding object database, the analysis of the big data (e.g., the appearance data of the reference feeding objects) can enable mining the complex corresponding relationship between the target image and the appearance feature of the feeding object, and realize the accurate determination of the appearance feature of the feeding object based on the target image.

FIG. 6 is a schematic diagram illustrating an exemplary process 600 for determining a breed-specific feature of a feeding object according to some embodiments of the present disclosure.

As illustrated in FIG. 6, in some embodiments, a target image 610 including a feeding object may be input into a breed recognition model 620, and the breed recognition model 620 may output a breed-specific feature 630 of the feeding object.

The breed recognition model 620 refers to a process or an algorithm for determining the breed-specific feature 630 of the feeding object based on the target image 610 of the feeding object. In some embodiments, the breed recognition model 620 may be a trained machine learning model. For example, the breed recognition model 620 may include a convolutional neural network (CNN), a deep neural network (DNN), a recurrent neural network (RNN), a long short term memory (LSTM) network model, a fully convolutional neural network (FCN) model, a generative adversarial network (GAN) model, a radial basis function (RBF) machine learning model, a DeepMask model, a SegNet model, a dilated convolution model, a conditional random fields as recurrent neural networks (CRFasRNN) model, a pyramid scene parsing network (pspnet) model, or the like, or any combination thereof.

In some embodiments, the breed recognition model 620 may be obtained by training an initial breed recognition model 640 based on a plurality of training samples 650 (also referred to as second training samples). In some embodiments, each of the plurality of training samples 650 may include a sample image of a sample feeding object as an input of the initial breed recognition model 640, and a sample breed-specific feature of the sample feeding object as a label.

The sample image may be obtained in a similar manner as how the target image is obtained as described in operation 302. The sample breed-specific feature may be determined in a similar manner as how the sample appearance feature 444 is determined. The initial breed recognition model 640 may be trained in a similar manner as how the initial feature determination model is trained as described in FIG. 4.

In traditional animal classification, the focus has primarily been on distinguishing between different species of animals, such as cats and dogs, with limited algorithms designed for finer-grained classification within the same species, resulting in lower accuracy. Some embodiments of the present disclosure introduce an animal breed classification algorithm capable of distinguishing dozens or even hundreds of breeds within the same species. By leveraging multi-dimensional feature learning of animal images, the breed-specific feature of the feeding object can be determined with greater precision and accuracy.

FIG. 7 is a schematic diagram illustrating an exemplary process 700 for determining a body size feature of a feeding object according to some embodiments of the present disclosure.

In 702, the processing device 140 (e.g., the determination module 220) may determine whether a reference object is a known reference object.

The known reference object refers to an object whose size is known. For example, the known reference object may be an item with a known size in a merchant database, such as, a feeding bowl, a feeding bowl stand, etc. As another example, the known reference object may be an object in a fixed size, such as, a Coca Cola bottle, A4 paper, etc. As still another example, the known reference object may be an object whose size of the object has been measured and recorded.

In some embodiments, the processing device 140 may determine whether the reference object is a known reference object through manners, such as target detection, image comparison, etc.

If the reference object is a known reference object, the processing device 140 may proceed to operation 704.

In 704, the processing device 140 (e.g., the determination module 220) may obtain the size of the reference object based on a record of the reference object. The record may record the size of the reference object. For example, the processing device 140 may construct a record database storing candidate records of candidate reference objects, and retrieve the record of the reference object from the record database based on the reference object to obtain the size of the reference object.

By obtaining the size of the reference object from the record of the reference object, the efficiency of the data processing can be improved, and the user operations can be simplified.

In some embodiments, the processing device 140 may identify the feeding object and the reference object from the target image, which can avoid that the target image includes no reference object and the user needs to place the reference object, thereby improving the efficiency and accuracy of the determination of the size of the reference object and enhancing the degree of automation.

If the reference object is not a known reference object, the processing device 140 may proceed to operation 706.

In 706, the processing device 140 (e.g., the determination module 220) may receive a user input of the size of the reference object. For example, the processing device 140 may prompt a user to input the size of the reference object. The user may input the size of the reference object through a terminal device (e.g., the at least one terminal device 130), and the processing device 140 may receive the user input of the size of the reference object via a network (e.g., the network 120).

After the size of the reference object is obtained, the processing device 140 may proceed to operation 708.

In 708, the processing device 140 (e.g., the determination module 220) may determine a body size feature of the feeding object based on the size of the reference object and a dimensional relationship between the feeding object and the reference object.

The dimensional relationship may indicate a dimensional transformation between the feeding object and the reference object. For example, the dimensional relationship may include a positional relationship (e.g., a distance, an angle, etc.), an occlusion relationship, a perspective proportion, etc., between the feeding object and the reference object.

For example, the processing device 140 may estimate the body size feature of the feeding object based on the distance, the perspective proportion between the feeding object and the reference object, and the size of the reference object.

By estimating the body size feature of the feeding object (e.g., a pet) based on the size of the reference object, the difficulty of manually measuring a restless feeding object can be avoided, thereby improving the efficiency and accuracy of the determination of the body size feature of the feeding object.

FIG. 8 is a schematic diagram illustrating an exemplary process 800 for updating an appearance feature of a feeding object according to some embodiments of the present disclosure.

In 802, the processing device 140 (e.g., the determination module 220) may send an appearance feature of the feeding object to a user.

For example, the processing device 140 may send the appearance feature of the feeding object to a user terminal (e.g., the at least one terminal device 130).

In 804, the processing device 140 (e.g., the determination module 220) may receive user feedback on the appearance feature of the feeding object.

For example, the user may check the appearance feature of the feeding object, and input the user feedback through the at least one terminal device 130. Correspondingly, the processing device 140 may receive the user feedback.

The user feedback may indicate whether the appearance feature needs to be updated. For example, if the user confirms the appearance feature, the user feedback may indicate that the appearance feature does not need to be updated. If the user determines that at least a portion of the appearance feature needs to be updated (e.g., added, removed, amended), the user feedback may indicate that the appearance feature needs to be updated.

The user feedback may be represented in various manners, such as, words, letters, numbers, etc. For example, when the appearance feature needs to be updated, the user feedback may be “1.” When the appearance feature does not need to be updated, the user feedback may be “0.”

In some embodiments, when the appearance feature needs to be updated, the user feedback may further include updated information regarding the appearance feature of the feeding object.

In 806, in response to determining that the user feedback indicates the appearance feature needs to be updated, the processing device 140 (e.g., the determination module 220) may update the appearance feature based on the user feedback.

For example, the processing device 140 may update the appearance feature based on the updated information in the user feedback.

Merely by way of example, when a breed of a feeding object (e.g., a Husky) is determined as “Norwegian Lundehund,” the processing device 140 may update the breed of the feeding object to be “Husky” based on user feedback indicating that the breed of the feeding object is “Husky.”

In 808, the processing device 140 (e.g., the determination module 220) may add the target image including the feeding object and the updated appearance feature to a training sample set of a feature determination model.

For example, the processing device 140 may designate the target image including the feeding object and the updated appearance feature as a first training sample. That is, the target image including the feeding object may be designated as an input of the initial feature determination model, and the updated appearance feature may be designated as a label corresponding to the input.

By introducing the user feedback, the appearance feature output by the feature determination model can be verified, thereby ensuring the accuracy of the appearance feature. In addition, the training sample set can be expanded, which can persistently train and/or update the feature determination model, further improving the performance of the feature determination model and the accuracy of the appearance feature.

FIG. 9A is a schematic diagram illustrating an exemplary process 900A for determining a recommended parameter relating to a feeding bowl for a feeding object according to some embodiments of the present disclosure.

As illustrated in FIG. 9A, in some embodiments, an appearance feature 910 (including a breed-specific feature 912, a body size feature 914, and a body proportion feature 916) of a feeding object may be input into a recommendation model 940, and the recommendation model 940 may output a recommended parameter 950 (including a type 952, a size 954, and a depth 956) relating to a feeding bowl for the feeding object.

The recommendation model 940 refers to a process or an algorithm for determining the recommended parameter 950 of the feeding object based on the appearance feature 910 of the feeding object. In some embodiments, the recommendation model 940 may be a trained machine learning model. For example, the recommendation model 940 may include a convolutional neural network (CNN), a deep neural network (DNN), a recurrent neural network (RNN), a long short term memory (LSTM) network model, a fully convolutional neural network (FCN) model, a generative adversarial network (GAN) model, a radial basis function (RBF) machine learning model, a DeepMask model, a SegNet model, a dilated convolution model, a conditional random fields as recurrent neural networks (CRFasRNN) model, a pyramid scene parsing network (pspnet) model, or the like, or any combination thereof.

In some embodiments, the recommendation model 940 may be obtained by training an initial recommendation model based on a plurality of training samples 960 (also referred to as third training samples). In some embodiments, each of the plurality of training samples 960 may include a sample appearance feature (including a sample breed-specific feature 961, a sample body size feature 962, and a sample body proportion feature 963) of a sample feeding object as an input of the initial recommendation model, and gold standard recommended parameters 966 of a sample feeding bowl corresponding to the sample feeding object as a label (also referred to as a second label).

The sample appearance feature (e.g., the sample breed-specific feature 961, the sample body size feature 962, and the sample body proportion feature 963) may be determined in a similar manner as how the appearance feature is determined as described in operation 304. The gold standard recommended parameters 966 may be determined automatically or manually. For example, a user (e.g., a feeder) may determine the gold standard recommended parameters 966 based on the sample appearance feature. In some embodiments, the processing device 140 may obtain the plurality of training samples 960 by retrieving (e.g., through a data interface) a database or a storage device.

During the training of the initial recommendation model, the plurality of training samples 960 may be input into the initial recommendation model, and parameter(s) of the initial recommendation model may be updated through one or more iterations. For example, the processing device 140 may input the sample appearance feature of each third training sample into the initial recommendation model, and obtain a second prediction result. The processing device 140 may determine a loss function (also referred to as a second loss function) based on the second prediction result and the second label (i.e., the corresponding gold standard recommended parameters 966) of each third training sample. The loss function may be associated with a difference between the second prediction result and the second label. The processing device 140 may adjust the parameter(s) of the initial recommendation model based on the loss function to reduce the difference between the second prediction result and the second label, for example, by continuously adjusting the parameter(s) of the initial recommendation model to reduce or minimize the loss function.

In some embodiments, the second loss function may be a perceptual loss function, a squared loss function, an exponential loss function, a logistic regression loss function, a quadratic loss function, etc.

In some embodiments, the recommendation model 940 may also be obtained according to other training manners. For example, the recommendation model 940 may be obtained based on an initial learning rate (e.g., 0.1) and/or an attenuation strategy using the plurality of training samples 960.

It should be noted that the recommendation model is merely provided for illustration purposes, and can be modified according to an actual need.

For example, the processing device 140 may determine a weight value for each of the breed-specific feature 912, the body size feature 914, and the body proportion feature 916. Therefore, the influences of the breed-specific feature, the body size feature, and the body proportion feature on the recommended parameter can be weighted, thereby improving the accuracy of the determination of the recommended parameter.

As another example, a feeding feature 920 and/or a growing feature 930 of the feeding object may be input into the recommendation model 940 with the appearance feature 910. As illustrated in FIG. 9A, the processing device 140 may determine the recommended parameter 950 for the feeding object by inputting the feeding feature 920 and/or the growing feature 930 together with the appearance feature 910 into the recommendation model 940. Correspondingly, each of the plurality of training samples 960 may include a sample feeding feature 964 and/or a sample growing feature 965 of the sample feeding object.

In some embodiments, the recommendation model 940 may include a plurality of recommendation units for determining the type 952, the size 954, and the depth 956, respectively. Merely by way of example, as illustrated in FIG. 9B, the recommendation model 940 may include a first recommendation unit 942, a second recommendation unit 944, and a third recommendation unit 946. The first recommendation unit 942 may be configured to determine the type 952 of the feeding bowl based on the breed-specific feature 912, and the second recommendation unit 944 may be configured to determine the size 954 of the feeding bowl based on the body size feature 914 and the type 952 of the feeding bowl, and the third recommendation unit 946 may be configured to determine the depth 956 of the feeding bowl based on the body proportion feature 916, and the type 952 and the size 954 of the feeding bowl.

For example, if the feeding object is a Husky with a long nose (e.g., a ratio of a nose length of the Husky to a distance between the nose to the mouth of the Husky is larger than a ratio threshold) and a large weight (larger than an average weight of Husky), the first recommendation unit 942 may determine the type 952 of the feeding bowl as a plate based on the breed-specific feature 912 (the Husky with the long nose), the second recommendation unit 944 may determine the size 954 of the feeding bowl as a large size based on the body size feature 914 (the large weight) and the type 952 (the plate), and the third recommendation unit 946 may determine the depth 956 of the feeding bowl as 50 centimeters based on the body proportion feature 916 (a large ratio of the nose length to the distance between the nose to the mouth) and the type and the size of the feeding bowl (the plate with the large size).

In some embodiments, the recommendation model 940 may be generated by training an initial recommendation model including a preliminary first recommendation unit, a preliminary second recommendation unit, and a preliminary third recommendation unit using the plurality of training samples. For example, the preliminary first recommendation unit, the preliminary second recommendation unit, and the preliminary third recommendation unit may be jointly trained to generate the recommendation model 940. For instance, for each of the plurality of training samples 960, the processing device 140 may input the sample breed-specific feature 961 of the third training sample into the preliminary first recommendation unit, and the preliminary first recommendation unit may output a predicted type of the sample feeding bowl. Then, the processing device 140 may input the sample body size feature 962 of the third training sample and the predicted type of the sample feeding bowl into the preliminary second recommendation unit, and the preliminary second recommendation unit may output a predicted size of the sample feeding bowl. Further, the processing device 140 may input the sample body proportion feature 963 of the third training sample, and the predicted type and the predicted size of the sample feeding bowl into the preliminary third recommendation unit, and the preliminary third recommendation unit may output a predicted depth of the sample feeding bowl. The processing device 140 may determine a loss function (also referred to as a third loss function) based on the predicted type, the predicted size, and the predicted depth of the sample feeding bowl and the second label (i.e., the corresponding gold standard recommended parameters 966) of each third training sample. The third loss function may be associated with a difference between the predicted type, the predicted size, and the predicted depth of the sample feeding bowl and the second label. The processing device 140 may adjust the parameter(s) of the initial recommendation model based on the third loss function to reduce the difference between the predicted type, the predicted size, and the predicted depth of the sample feeding bowl and the second label, for example, by continuously adjusting the parameter(s) of the initial recommendation model to reduce or minimize the third loss function.

In some embodiments, the third loss function may be similar to the second loss function and/or the first loss function.

As another example, the recommendation model 940 may be generated by training the first recommendation unit 942, the second recommendation unit 944, and the third recommendation unit 946, respectively.

By introducing the recommendation model, the recommended parameter may be determined automatically, which can improve the efficiency of the determination of the recommended parameter. In addition, a corresponding relationship between the appearance feature (e.g., the breed-specific feature, the body size feature, and the body proportion feature) and the recommended parameter (e.g., the type, the size, and the depth) may be complex. By using the machine learning model (e.g., the recommendation model), the analysis of the big data may enable mining the complex corresponding relationship, and realize the accurate determination of the recommended parameter based on the appearance feature.

It should be noted that the descriptions of the processes 300-900B are provided for the purposes of illustration, and are not intended to limit the scope of the present disclosure. For persons having ordinary skills in the art, various variations and modifications may be conducted under the teaching of the present disclosure. For example, the processes 300-900B may be accomplished with one or more additional operations not described, and/or without one or more of the operations discussed. Additionally, the order in which the operations of the processes 300-900B is not intended to be limiting. However, those variations and modifications may not depart from the protection of the present disclosure.

Some embodiments of the present disclosure further provide an electronic device. The electronic device includes at least one storage medium storing computer instructions, and at least one processor. When the at least one processor executes the computer instructions, the method for object feeding described in the present disclosure may be implemented. The electronic device may also include an input/output device. The input/output device may be connected to the at least one processor. More descriptions regarding the techniques may be found in elsewhere in the present disclosure. See, e.g., FIGS. 1 to 9B, and relevant descriptions thereof.

Some embodiments of the present disclosure further provide a non-transitory computer-readable storage medium that stores the computer instruction. When reading the instruction, a computer may execute the method for object feeding described in the present disclosure. More descriptions regarding the techniques may be found in elsewhere in the present disclosure. See, e.g., FIGS. 1 to 9B, and relevant descriptions thereof.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended for those skilled in the art, though not expressly stated herein. These alterations, improvements, and modifications are intended to be suggested by this disclosure, and are within the spirit and scope of the exemplary embodiments of this disclosure.

Moreover, certain terminology has been used to describe embodiments of the present disclosure. For example, the terms “one embodiment,” “an embodiment,” and/or “some embodiments” mean that a particular feature, structure, or characteristic described in connection with the embodiment is included in at least one embodiment of the present disclosure. Therefore, it is emphasized and should be appreciated that two or more references to “an embodiment” or “one embodiment” or “an alternative embodiment” in various portions of this disclosure are not necessarily all referring to the same embodiment. Furthermore, the particular features, structures, or characteristics may be combined as suitable in one or more embodiments of the present disclosure.

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose, and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various inventive embodiments. This method of disclosure, however, is not to be interpreted as reflecting an intention that the claimed subject matter requires more features than are expressly recited in each claim. Rather, inventive embodiments lie in less than all features of a single foregoing disclosed embodiment.

In some embodiments, the numbers expressing quantities or properties used to describe and claim certain embodiments of the application are to be understood as being modified in some instances by the term “about,” “approximate,” or “substantially.” For example, “about,” “approximate,” or “substantially” may indicate ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the application are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes, excepting any prosecution file history associated with same, any of same that is inconsistent with or in conflict with the present document, or any of same that may have a limiting effect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that may be employed may be within the scope of the application. Thus, by way of example, but not of limitation, alternative configurations of the embodiments of the application may be utilized in accordance with the teachings herein. Accordingly, embodiments of the present application are not limited to that precisely as shown and described.

What is claimed is:

1. A method for object feeding, implemented on a computing device comprising at least one processor and at least one storage device, the method comprising:
obtaining a target image including a feeding object;
determining, based on the target image, an appearance feature of the feeding object, the appearance feature at least including a breed-specific feature, a body size feature, and a body proportion feature; and
determining, based on the appearance feature of the feeding object, a recommended parameter relating to a feeding bowl for the feeding object through a recommendation model, wherein the recommendation model is a machine learning model.

2. The method of claim 1, wherein the determining, based on the target image, an appearance feature of the feeding object includes:
determining the appearance feature of the feeding object by inputting the target image into a feature determination model, wherein the feature determination model is a machine learning model.

3. The method of claim 1, wherein the determining, based on the target image, an appearance feature of the feeding object includes:
determining, based on the target image, the breed-specific feature of the feeding object;
determining, based on the target image, the body size feature of the feeding object; and
determining the body proportion feature of the feeding object based on the breed-specific feature and the body size feature of the feeding object.

4. The method of claim 3, wherein the target image includes a reference object, and the determining, based on the target image, the body size feature of the feeding object includes:
obtaining a size of the reference object; and
determining the body size feature of the feeding object based on the size of the reference object and a dimensional relationship between the feeding object and the reference object.

5. The method of claim 4, wherein the obtaining a size of the reference object includes:
determining whether the reference object is a known reference object;
in response to determining that the reference object is a known reference object, obtaining the size of the reference object based on a record of the reference object; or
in response to determining that the reference object is not a known reference object, receiving a user input of the size of the reference object.

6. The method of claim 3, wherein the determining, based on the target image, the body size feature of the feeding object includes:
obtaining imaging information relating to the target image, the imaging information at least including parametric information of an image acquisition device used for collecting the target image; and
determining the body size feature of the feeding object based on the target image and the imaging information.

7. The method of claim 3, wherein the determining the body proportion feature of the feeding object based on the breed-specific feature and the body size feature of the feeding object includes:
retrieving the body proportion feature of the feeding object from a feeding object database based on the breed-specific feature and the body size feature of the feeding object, wherein the feeding object database is constructed based on appearance data of reference feeding objects of a plurality of breeds.

8. The method of claim 7, wherein the retrieving the body proportion feature of the feeding object from a feeding object database based on the breed-specific feature and the body size feature of the feeding object includes:
determining a key feature value of the feeding object based on the body size feature of the feeding object; and
retrieving the body proportion feature of the feeding object from the feeding object database by matching the key feature value and the breed-specific feature of the feeding object with candidate body proportion features in the feeding object database.

9. The method of claim 1, wherein the target image includes multiple target images, and the appearance feature of the feeding object is determined by:
constructing a three-dimensional (3D) model of the feeding object based on the multiple target images; and
determining, based on the 3D model of the feeding object, the appearance feature of the feeding object.

10. The method of claim 1, wherein the determining, based on the appearance feature of the feeding object, a recommended parameter relating to a feeding bowl for the feeding object through a recommendation model includes:
obtaining a feeding feature of the feeding object; and
determining the recommended parameter for the feeding object by inputting the appearance feature and the feeding feature of the feeding object into the recommendation model.

11. The method of claim 1, further comprising:
obtaining a feeding feature of the feeding object;
determining, based on the feeding feature, an adjustment coefficient of the recommended parameter; and
adjusting the recommended parameter based on the adjustment coefficient.

12. The method of claim 1, further comprising:
sending the appearance feature of the feeding object to a user;
receiving user feedback on the appearance feature of the feeding object; and
in response to determining that the user feedback indicates the appearance feature needs to be updated, updating the appearance feature based on the user feedback.

13. The method of claim 1, further comprising:
sending the recommended parameter to a user.

14. The method of claim 1, wherein the recommended parameter at least includes a type, a size, and a depth of the feeding bowl for the feeding object.

15. The method of claim 14, wherein the recommendation model includes a first recommendation unit, a second recommendation unit, and a third recommendation unit, wherein
the first recommendation unit is configured to determine the type of the feeding bowl based on the breed-specific feature,
the second recommendation unit is configured to determine the size of the feeding bowl based on the body size feature and the type of the feeding bowl, and
the third recommendation unit is configured to determine the depth of the feeding bowl based on the body proportion feature, and the type, and the size of the feeding bowl.

16. The method of claim 15, wherein the recommendation model is generated by:
obtaining a plurality of training samples, each of the plurality of training samples including sample breed-specific feature, sample body size feature, and sample body proportion feature of a sample feeding object and gold standard recommended parameters of a sample feeding bowl corresponding to the sample feeding object;
generating the recommendation model by training an initial recommendation model including a preliminary first recommendation unit, a preliminary second recommendation unit, and a preliminary third recommendation unit using the plurality of training samples,
wherein in the training process,
a predicted type of the sample feeding bowl output by the preliminary first recommendation unit is input in the preliminary second recommendation unit with the sample body size feature, and the preliminary second recommendation unit outputs a predicted size of the sample feeding bowl, and
the predicted type and the predicted size of the sample feeding bowl are input in the preliminary third recommendation unit with the sample body proportion feature, and the preliminary third recommendation unit outputs a predicted depth of the sample feeding bowl.

17. The method of claim 16, wherein each of the plurality of training samples further includes at least one of a sample feeding feature and a sample growing feature of the sample feeding object.

18. The method of claim 15, wherein the body proportion feature includes a ratio of a nose length of the feeding object to a distance between the nose to the mouth of the feeding object, and the third recommendation unit is further configured to determine the depth of the feeding bowl based on the ratio, and the type and the size of the feeding bowl.

19. A system for object feeding, comprising:
at least one storage device including a set of instructions; and
at least one processor in communication with the at least one storage device,
wherein when executing the set of instructions, the at least one processor is directed to perform operations including:
obtaining a target image including a feeding object;
determining, based on the target image, an appearance feature of the feeding object, the appearance feature at least including a breed-specific feature, a body size feature, and a body proportion feature; and
determining, based on the appearance feature of the feeding object, a recommended parameter relating to a feeding bowl for the feeding object through a recommendation model, wherein the recommendation model is a machine learning model.

20. A non-transitory computer readable medium, comprising executable instructions that, when executed by at least one processor, direct the at least one processor to perform a method for object feeding, the method comprising:
obtaining a target image including a feeding object;
determining, based on the target image, an appearance feature of the feeding object, the appearance feature at least including a breed-specific feature, a body size feature, and a body proportion feature; and
determining, based on the appearance feature of the feeding object, a recommended parameter relating to a feeding bowl for the feeding object through a recommendation model, wherein the recommendation model is a machine learning model.
